(19) United States
(12) Patent Application Publication
(10) Pub. No.: US 2004/0183166 A1
(43) Pub. Date: Sep. 23, 2004

(54) Preplated leadframe without precious metal

(76) Inventor: Donald C. Abbott, Norton, MA (US)

Correspondence Address: TEXAS INSTRUMENTS INCORPORATED, P O BOX 655474, M/S 3999, DALLAS, TX, 75265

(21) Appl. No.: 10/389,875

(22) Filed: Mar. 17, 2003

(51) Int. Cl. H01L 23/495

(52) U.S. Cl. 257/666

(57) ABSTRACT

A leadframe for use in the assembly of integrated circuit (IC) chips, which has a base metal structure (506) with an adherent layer (507) of a bondable and solderable electronegative metal. Adhering to the first layer (507) is a layer of a second metal (508), which provides improved adhesion to molding compounds and is deposited thin enough to permit a bond to the first metal. This second metal may be less electronegative than the first metal. A third adherent layer (510), formed of the second metal, is selectively covering leadframe areas intended for attachment to external parts and has a thickness suitable for such attachment.

### FIELD OF THE INVENTION

The present invention is related in general to the field of semiconductor devices and processes, and more specifically to the materials and fabrication of leadframes for integrated circuit devices.

### DESCRIPTION OF THE RELATED ART

Within a majority of packages for semiconductor devices, metallic leadframes are employed. They provide a stable support pad for firmly positioning the semiconductor chip, usually an integrated circuit (IC) chip, within the package. In addition, the leadframe offers a plurality of conductive segments to bring various electrical conductors into close proximity of the chip. The remaining gap between the inner tip of the segments and the contact pads on the IC surface are typically bridged by thin metallic wires individually bonded to the IC contact pads and the leadframe segments. In order to ensure reliable bonding of the wires to the metal of the leadframe, a spot of noble metal is typically located where the bond is to be affixed.

The ends of the lead segment remote from the IC chip (“outer” tips) need to be electrically and mechanically connected to external circuitry, for instance to assembly printed circuit boards. In the overwhelming majority of electronic applications, this attachment is performed by soldering, conventionally with lead-tin (Pb/Sn) eutectic solder at a reflow temperature in the 210 to 220° C. range. In order to ensure wettability of the leadframe segments in the soldering process, the outer segment tips frequently have a layer of noble metal.

Finally, the leadframe provides the framework for encapsulating the sensitive chip and fragile connecting wires. Encapsulation using plastic materials, rather than metal cans or ceramic, has been the preferred method because of low cost. The transfer molding process for epoxy-based thermoset compounds at 175° C. has been practiced for many years. In order to ensure good adhesion between the molding compound and the leadframe, the leadframe is frequently coated with a layer of noble metal with affinity to epoxy-based compounds.

The recent general trend to avoid lead in the electronics industry and use lead-free solders, pushes the reflow temperature range into the neighborhood of about 260° C. This higher reflow temperature range makes it more difficult to maintain the mold compound adhesion to the leadframes required to avoid device delamination during reliability testing at high moisture levels. Furthermore, the inclination to use pure tin for soldering raises the risk of tin dendrite/whisker growth, a generally feared reliability failure phenomenon.

Nickel plating of the leadframe starting metal has been shown to be desirable because nickel reduces the propensity for tin dendrite/whisker growth in devices with tin-plated leads. Nickel, however, has poor adhesion to most molding compounds. In a frequently practiced solution, it is coated with a thin layer of noble metal.

As far as cost is concerned, the leadframes represent the lion's share of the package material cost; specifically, a significant part of that cost is contributed by the noble and thus precious metals used in these leadframes for the purposes listed above.

Unfortunately, the prices of most noble metals have been climbing strongly during the last few years, and this price increase is expected to continue into the foreseeable future. In addition, the ever-present pressure for cost reduction in the semiconductor industry continues unabated.

It is therefore not surprising that a need has arisen for a comprehensive strategy to reduce cost of leadframes and thus semiconductor packages. The solution for lower cost leadframes also has to include the goal of reliable leadframes, including adhesion to molding compounds, bondability for connecting wires, and avoidance of tin dendrite growth. The leadframe and its method of fabrication should be low cost and flexible enough to be applied for different semiconductor product families and a wide spectrum of design and assembly variations, and should achieve improvements toward the goals of improved process yields and device reliability. Preferably, these innovations should be accomplished using the installed equipment base so that no investment in new manufacturing machines is needed.

### SUMMARY OF THE INVENTION

One embodiment of the invention is a leadframe for use in the assembly of integrated circuit (IC) chips, which includes a base metal structure with an adherent first layer comprising a bondable and solderable electronegative metal. Adhering to the first layer is a layer of a second metal which is deposited thin enough to permit a bond to the first metal. This second metal may be less electronegative than the first metal. A third adherent layer, formed of the second metal, selectively covers leadframe areas intended for attachment to external parts and has a thickness suitable for such attachment. As a fully “pre-plated” part, the leadframe is then submitted to the assembly process of the semiconductor device.

The metal of the second layer is further selected so that it provides improved adhesion to molding compounds, and the metal of the first layer is selected so that it suppresses whisker formation of the second metal. Preferred choices for the first metal include nickel, and for the second metal tin (second and third layer).

In another embodiment of the invention, the third adherent metal layer, suitable for attachment to external parts, is deposited on selected areas of the leadframe only after completing the encapsulation process of the semiconductor device assembly. The leadframe of this embodiment of the invention is referred to as a “post-plated” part.

Embodiments of the present invention are related to high density ICs, especially those having high numbers of inputs/outputs, or contact pads, and also to devices in packages requiring surface mount in printed circuit board assembly. These ICs can be found in many semiconductor device families such as standard linear and logic products, digital signal processors, microprocessors, wireless devices, digital and analog devices, and both large and small area chip categories. The embodiments provide a significant cost reduction, since they do not use electropositive, i.e. noble and precious metals. The embodiments further enhance environmental protection and assembly flexibility of semiconductor packages, especially the plastic molded packages, compared to the conventional copper-based solder-plated leadframes.

It is a technical advantage of one or more embodiments of the invention that the embodiments can reach the goals of the invention with a low-cost manufacturing method without the cost of equipment changes and new capital investment, by using the installed fabrication equipment base.

Another advantage which may flow from one or more embodiments of the invention is to produce leadframes so that established wire bonding processes can continue unchanged, and so that established board attachment processes can continue unchanged. As an example, in one embodiment the leadframes prepared according to the invention can be successfully used in surface mount technologies based on bending the package lead segments. Embodiments of the invention generally apply to semiconductor package types such as PDIPs, SOICs, QFPs, SSOPs, TQFPs, TSSOPs, TVSOPs, and Ball Grid Array devices employing leadframes.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 is a schematic and simplified cross sectional view of a leadframe with base metal and a first plated layer.

FIG. 2 is a schematic and simplified cross sectional view of a leadframe after plating the second layer.

FIG. 3 is a schematic and simplified cross sectional view of a leadframe after plating the third layer in selected areas.

FIG. 4 is a schematic and simplified cross sectional view of a leadframe, which has been stamped after plating two metal layers on both sides and a third layer in selected areas.

FIG. 5 is a schematic and simplified cross sectional view of a packaged gull-wing semiconductor device.

FIG. 6 is a schematic and simplified cross sectional view of a packaged no-lead semiconductor device.

### DETAILED DESCRIPTION OF THE PREFERRED EMBODIMENTS

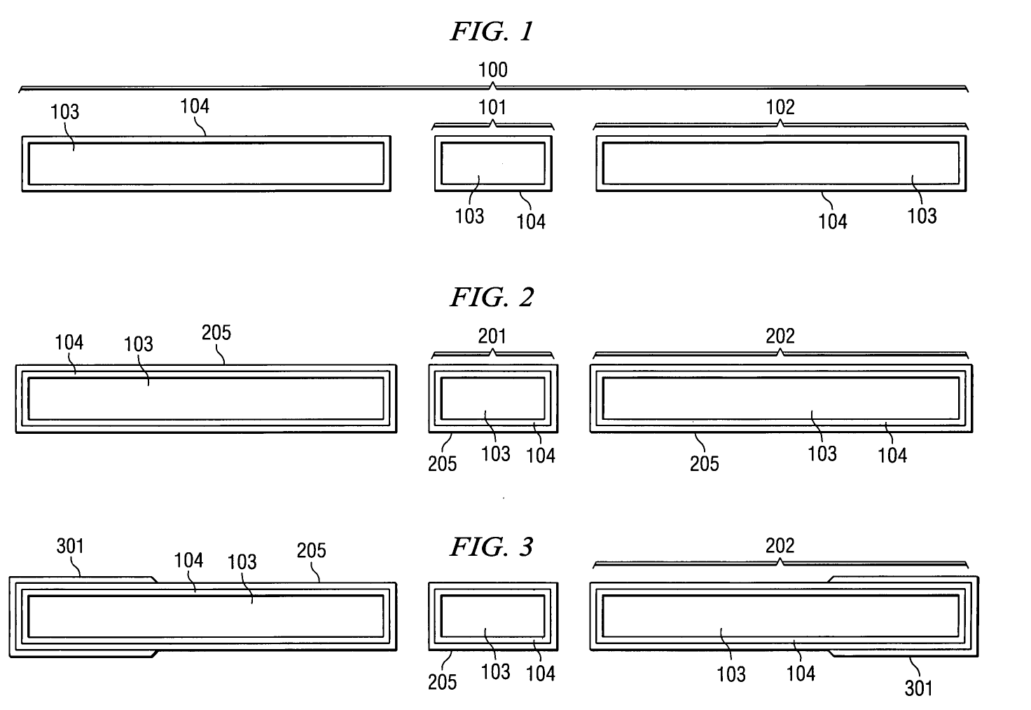

FIG. 1 is a schematic and simplified cross section of a leadframe portion, generally designated 100, and shows the chip mount pad 101 and a plurality of lead segments 102. The leadframe is made of a base metal 103 fully covered with a plated layer 104.

As defined herein, the starting material of the leadframe is called the “base metal”, indicating the fundamental or starting metal. Consequently, the term “base metal” is not to be construed in an electrochemical sense (as in opposition to ‘noble metal’) or in a hierarchical sense.

Base metal 103 is typically copper or a copper alloy. Other choices include brass, aluminum, iron-nickel alloys (“Alloy 42”), and invar.

Base metal 103 originates with a metal sheet in the preferred thickness range from 100 to 300 μm; thinner sheets are possible. The ductility in this thickness range provides the 5 to 15% elongation that facilitates the segment bending and forming operation. The leadframe is stamped or etched from the starting metal sheet.

The plated layer 104 is made of a bondable and solderable electronegative metal, covering the base metal and typically having a thickness between 0.2 and 1.0 μm. Preferred metals include nickel, cobalt and alloys thereof. These metals are not “noble” metals (which are electropositive and thus difficult to oxidize) and therefore not precious. Table I is a listing of electronegative and electropositive metals. Nickel in particular is favored because it reduces, when placed under tin or a tin-rich solder, the propensity for tin whiskers. Layer 104 is ductile for the leadframe segment bending and forming process. As a result of the plating process used, layer 104 is typically smooth.

Since smooth nickel or cobalt and their alloys do not adhere particularly well to molding compounds, an additional metal layer is needed to promote adhesion. In FIG. 2, layer 205 indicates this layer, which covers the first metal layer 104 in both the chip mount pad 201 and the plurality of lead segments 202. In this and other embodiments of the invention, the metal for layer 205 can be pure tin, or tin alloys such as tin/copper, tin/indium, tin/bismuth, tin/silver, and tin/lead. Preferably, the metal of layer 205 is less electronegative than the metal of layer 104, but not an electropositive metal such as palladium, gold or alloys thereof, which are conventionally used for promoting adhesion to molding compounds.

The thickness of layer 205 is preferably between 3 and 100 nm, but may even be less than 3 nm thick. In this thinness range, wire bonds, especially stitch bonds, can penetrate through layer 205 and accomplish the actual welding, or bond, directly on the metal of layer 104. At the temperatures of wire bonding (typically between 200 and 220° C.) and tin solder reflow (typically between 230 and 240° C.), the metal of layer 205 may interdiffuse with the metal of layer 104, and thus form an interdiffused metal region, which is a strong promoter of adhesion to molding compounds.

In summary, by the selection of metals (preferably tin) and the thinness of the layer (preferably low nanometer range), layer 205 enables two functions of the leadframe: it promotes good adhesion to molding compounds, and it permits reliable bonding to the underlying first metal layer (preferably nickel). The plating of layer 205 is preferably performed after stamping or etching of the leadframe from the starting sheet metal. This is taken into account in FIG. 2, where base metal 103 is covered by the plated layers 104 and 205 on all sides.

In one embodiment of the invention, the leadframe as described in FIG. 2 is submitted to the sequence of process steps for chip assembly and packaging without “pre-plating” solderable material such as tin or tin alloys needed for attachment to external parts; these materials are added by plating after completion of the encapsulation step.

In another embodiment, the needed solderable material such as tin or tin alloys is plated onto the leadframe while it is still in strip form. This embodiment is illustrated in FIG. 3, where adherent layer 301 covers the leadframe areas on the outer parts of segments 202, which are intended for attachment to external parts. Layer 301 consists of solderable, preferably reflowable material, including pure tin, tin alloys such as tin/copper, tin/indium, tin/bismuth, tin/silver, and tin/lead, indium, and conductive adhesive compounds. The preferred thickness range of layer 301 is from about 10 to 500 nm; if desired, it may be considerably thicker.

Whisker growth is inhibited by the layer 104 in FIG. 3, which is preferably nickel and is a diffusion barrier for the base metal 103 and also keeps the base metal out of the layer 205 and the subsequent solder joint. Further helpful for suppressing whisker growth is a matte, coarse grain of the preplated layer 301, and a low carbon content composition. An important contribution is further the fact that the layer 301 receives, due to its preplating deposition before the molding encapsulation process, a thorough annealing step during the extended molding compound polymerization period (“curing”; commonly at 175° C. for 5 to 6 hr). It is a technical advantage of the invention that this annealing step is provided without any additional time or cost during the assembly process.

The selective metal deposition of the layer 301 onto the leadframe uses an inexpensive, temporary masking step, which leaves only those leadframe portions exposed which are intended to receive the metal layer. Because of the fast plating time, conventional selective spot plating techniques can be considered, especially reusable rubber masks. For thin metal plating, a wheel system is preferred as described below.

There are several methods to selectively deposit metals from solution onto a continuous strip. For high volume production of leadframes, continuous strip or reel to-reel plating is advantageous and common practice. For applications where loose tolerances are acceptable for the boundaries of the metal layer plating, the preferred deposition method for the present invention is the so-called “wheel system”.

In the wheel system, material is moved over a large diameter wheel with apertures in it to allow solution flow to material. These apertures define the locations for plating and index pins engage the pilot holes in the leadframe. A backing belt is used to hold material on the wheel and a mask on the backside of the material. The anode is stationary inside the wheel. Among the advantages of the wheel system are a fast operating speed, since the material never stops for selective plating. There are no timing issues, and the pumps, rectifiers, and drive system are on continuously. The wheel system is low cost because the system is mechanically uncomplicated. However, the boundaries of plated layers are only loosely defined.

A more precise, but also more costly and slower selective plating technique is the step-and-repeat process. In the step-and-repeat system, the leadframe material is stopped in selective plating heads. A rubber mask system clamps on the material-to-be-plated. A plating solution is jetted at the material. Electrical current is applied and shut off after a pre-determined period of time. Then, the solution is shut off and the head opens. Thereafter, the material moves on. Among the advantages of the step-and-repeat system are a very sharp plating spot definition with excellent edges, further a very good spot location capability when used with index holes, pins and feedback vision system.

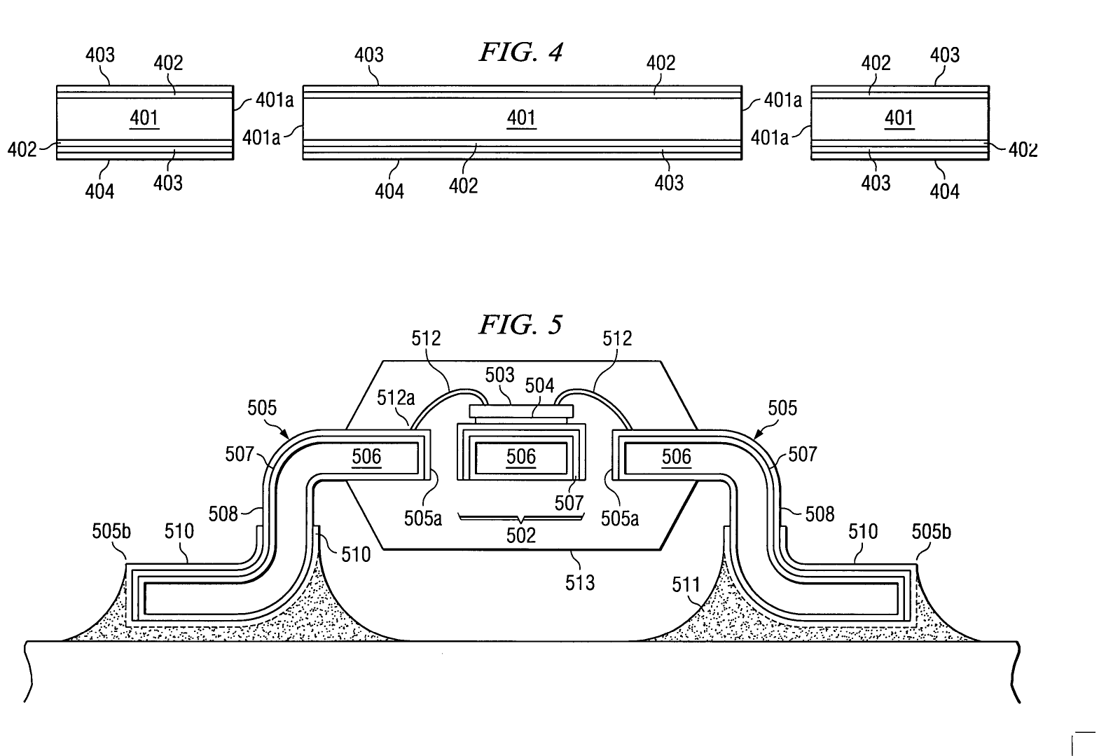

FIG. 4 illustrates yet another embodiment of the invention. In order to produce the embodiment of FIG. 4, the continuous sheet of base material is first plated with the desired sequence of layers and then stamped or etched into the desired structure. The base metal 401 may consist, for example, of copper, a copper alloy, brass, aluminum, an iron-nickel alloy (“Alloy 42”), or invar; the preferred thickness range is from 100 to 300 μm. The first layer 402 is plated on both sides of the base metal sheet. Layer 402 is bondable and solderable and is made, for instance, of nickel, cobalt, or an alloy thereof; the thickness range is typically from 0.2 to 1.0 μm. The second layer 403 is also plated on both sides of the sheet. Layer 403 ensures good adhesion to molding compounds and permits penetration of the wire bond to the bondable metal 402 underneath. Layer 403 consists, for example, of pure tin, tin alloys such as tin/copper, tin/indium, tin/bismuth, tin/silver and tin/lead, or indium. The preferred thickness range of layer 403 is from 3 to 100 nm.

The third layer 404 is only plated on the one sheet side, where the leadframe is intended for attachment to external parts. Preferably, layer 404 is made of reflowable material such as tin, tin alloys, indium, or conductive adhesive compounds. The thickness of layer 404 is preferably between 10 and 500 nm, but it may be thicker. Since layer 404 is selectively plated on only one side of the leadframe sheet, the fabrication is performed with one of the masking techniques described above.

The final step in the fabrication of this embodiment is the stamping or etching of the sheet, which produces the leadframe structure shown in schematic and simplified cross section in FIG. 4. When the metal sheet is stamped in the leadframe production, the base metal 401 is exposed on all edges 401a, which have been created by the stamping process of the leadframe structure. These exposed edges have been demonstrated to give superior adhesion to most molding compounds used in the fabrication of IC devices. This is especially true for copper and copper alloys, the typical base metals of leadframes. The stamping or etching step may be followed by a process step of selective etching, especially of the exposed base metal surfaces 401a, in order to create large-area contoured surfaces for improved adhesion to molding compounds.

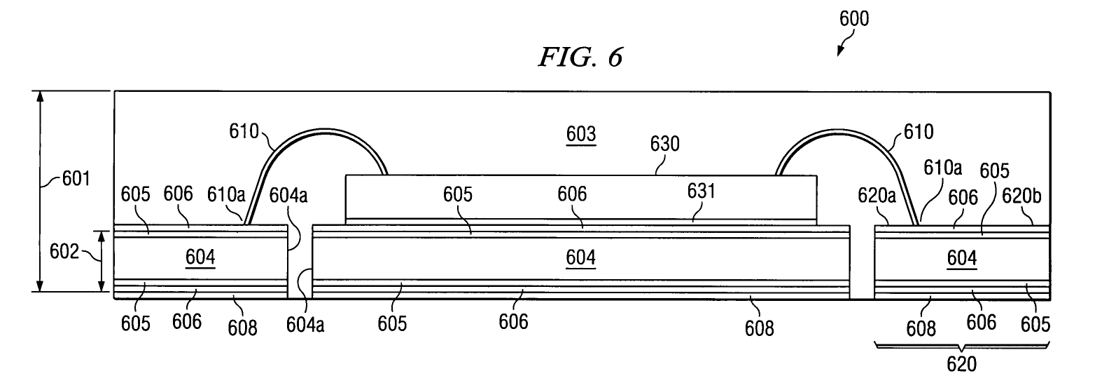

FIGS. 5 and 6 illustrate examples of semiconductor device applications of leadframes incorporating an embodiment of the invention. Both examples are molded surface mount devices, FIG. 5 is a small outline package with gull-wing shaped outer lead segments, FIG. 6 a small outline no-lead device.

In the schematic cross section of FIG. 5, the leadframe (for example copper or copper alloy) has a chip mount pad 502 onto which an IC chip 503 is attached using adhesive material 504 (typically an epoxy or polyimide which has to undergo polymerization). The leadframe further has a plurality of lead segments 505. These lead segments have a first end 505a near the chip mount pad 502 and their second end 505b remote from mount pad 502.

As shown in FIG. 5 schematically, the leadframe comprises base 506, preferably made of copper or copper alloy. On the surface of this base is a sequence of layers, described above in detail in reference to FIG. 3. Closest to the base metal is a first layer 507 of bondable and solderable electronegative metal such as nickel, cobalt or an alloy thereof. This layer 507 is followed by thin layer 508 of a metal with affinity to molding compounds, such as tin or tin alloy. In the thickness range 3 to 100 nm, the tin of layer 508 can be penetrated by bonding stitches to provide direct welding on the underlying metal of layer 507. Next, in selected areas, is a layer 510 of reflowable metal (for instance, tin or tin alloy). This layer 510 is incorporated into the meniscus of the bulk solder 511 in the process of surface mounting the small-outline device onto a substrate or board.

In FIG. 5, bonding wires 512 have stitches 512a welded to the bondable surface 507 of the first ends 505a of leadframe segments 505. The bonding wires may be chosen, for example, from gold, copper, aluminum, and alloys thereof, or other suitable electrically conductive interconnections. Any of these metals provide reliable welds to the metal layer 507.

As shown in FIG. 5, the second ends 505b of segments 505 are suitable for bending and forming due to the ductility of the base metal (for instance, copper) and the plated metal layers (for instance, nickel and tin). In general, copper leads plated with the nickel and tin of the invention have better trim/form performance than leads plated with the traditional lead/tin alloy due to improved ductility. Because of this malleability, segments 505 may be formed in any shape required for surface mounting or any other technique of board attachment of the semiconductor devices. The bending of the segments does not diminish the corrosion protection of the second segment ends 505b. For example, FIG. 5 indicates a so-called “gull wing shape” of segments 505.

In FIG. 5, solder attach material 511 comprises, for example, a solder paste; this paste may dissolve the plated layer 510 (indicated by the dashed lines in FIG. 5), resulting in good wetting characteristics of the plated nickel layer of the leadframe. In FIG. 5, molding compound 513 encapsulates the mounted chip 503, bonding wires 512 and the first ends 505a of the lead segments 505. The second, remote ends 505b of the segments are not included in the molded package; they remain exposed for solder attachment. Typically, the encapsulation material 513 is an epoxy-based molding compound suitable for adhesion to the leadframe surfaces.

The cross sectional side view of FIG. 6 illustrates an embodiment of the invention for a semiconductor small outline no-lead device. The device, generally designated 600, has been transfer molded to a total thickness 601 of about 0.8 mm, of which the leadframe sheet contributes a thickness 602 of about 0.1 mm and the encapsulation material 603 (preferably a molding compound) the remainder of 0.7 mm. The leadframe base metal 604 is preferably copper or copper alloy. The base material 604 has been plated before the stamping step. When the metal sheet is stamped in the leadframe production, the base metal is exposed to the molding material 603 on all edges 604a, which have been created by the stamping process of the leadframe structure. Copper or copper alloy, the typical metals of the leadframe, have been demonstrated to give superior mold compound adhesion to most mold compound used in the fabrication of IC devices.

Following the sequence of deposited metal layers described in reference to FIG. 4, FIG. 6 shows the bondable and solderable electronegative metal layer 605 (preferably nickel, cobalt or an alloy thereof), the thin layer 606 of a metal with affinity to molding compounds (preferably tin or tin alloy), and the solderable layer (examples include tin or tin alloys) 608. In the thickness range 3 to 100 nm, the tin of layer 606 can be penetrated by bonding stitches to provide direct welding on the underlying metal of layer 605. The good adhesion between layer 606 and molding compound is an attribute crucial for avoiding package delamination and progressive corrosion.

As can be seen in FIG. 6, the plated layer 608 of solderable material is available on all leadframe portions facing the “outside world” for solder attachment to other parts. When a pure tin or tin solder alloy is chosen as plating material, the layer thickness is preferably in the range from about 3 to 25 μm. As reflowable materials, layer 608 may, for example, comprise tin, tin alloys such as tin/copper, tin/indium, tin/silver, and tin/bismuth, indium, tertiary alloys (also containing gallium), and conductive adhesive compounds. A preferred easy-to-plate solder alloy is a binary tin and copper alloy; a tin and silver alloy is another preferred solder. The composition is optimized to bring the reflow temperature above the temperatures seen at the various assembly steps (chip attach, wire bonding, molding, curing), which vary from device to device. For example, if 270° C. is the target, 2.5 weight % copper is appropriate in the tin/copper alloy; if 300° C. is the target, 5.0 weight % copper is appropriate. The tin/copper, or tin/silver alloy does not need to melt, but will rather dissolve into the solder paste, offering good wettablilty of the underlying nickel.

In FIG. 6, bonding wires 610 have stitches 610a welded to the nickel layer 605 of the first ends 620a of leadframe segments 620. The bonding wires are preferably made of gold, copper, aluminum, and alloys thereof. Any of these metals provide reliable welds to the metal of layer 605.

With the outer leadframe surface plated with layer 608 preferably made of tin or a tin alloy, the embodiment of the invention provides for easy and reliable solder attachment to boards or other external parts. When solder pastes are used, the paste may dissolve the plated tin layer, resulting in good wetting characteristics to the plated nickel layer 605.

In FIG. 6, molding compound 603 encapsulates the chip 630 mounted by adhesive layer 631, bonding wires 610 and at least the first ends 620a of the lead segments 620. The second, remote ends 620b of the segments may or may not be encapsulated, dependent on the device type. Typically, the encapsulation material 603 is selected from epoxy-based molding compounds suitable for adhesion to the leadframe surfaces.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the material of the semiconductor chip may comprise silicon, silicon germanium, gallium arsenide, or any other semiconductor or compound material used in IC manufacturing.

As another example, the process step of stamping the leadframes from a sheet of base metal may be followed by a process step of selective etching, especially of the exposed base metal surfaces in order to create large-area contoured surfaces for improved adhesion to molding compounds.

It is therefore intended that the appended claims encompass any such modifications or embodiments.

I claim:

1. A leadframe, comprising:
a base metal structure;
an adherent first layer of electronegative metal covering said base metal;
an adherent second metal layer covering said first layer, said second metal layer being less electronegative than the first layer metal; and
an adherent third layer of said second metal selectively covering areas of said second layer intended for attachment to external parts.

2. The leadframe according to claim 1 wherein said base metal is copper, copper alloy, brass, aluminum, iron-nickel alloy, or invar.

3. The leadframe according to claim 1 wherein said first layer metal is nickel, cobalt, or an alloy thereof.

4. The leadframe according to claim 1 wherein said second layer metal is less electronegative than said first layer metal.

5. The leadframe according to claim 1 wherein said second layer metal is tin or tin alloy including tin/copper, tin/indium, tin/bismuth, tin/silver, and tin/lead.

6. The leadframe according to claim 1 wherein the second layer thickness is between about 3 and 100 nm.

7. The leadframe according to claim 1 wherein said third layer is between about 10 and 500 nm thick.

8. A semiconductor device, comprising:
a leadframe having a chip mount pad and a plurality of lead segments, each said segment having a first end near said mount pad and a second end remote from said mount pad;
said leadframe comprising a base metal and a first adherent layer of electronegative metal covering said base metal;
said leadframe further comprising an adherent second metal layer being less electronegative than said first layer metal, and an adherent third layer of said second metal selectively covering areas intended for attachment to external parts;
an integrated circuit chip attached to said mount pad;
bonding wires interconnecting said chip and said first segment ends, wherein said interconnection includes bonds through said second layer to said first layer;
encapsulation material covering said chip, bonding wires and said first ends of said lead segments, leaving uncovered leadframe parts intended for attachment to external parts.

9. The device according to claim 7 wherein said base metal is copper, copper alloy, brass, aluminum, iron-nickel alloy, or invar.

10. The device according to claim 7 wherein said first layer metal is nickel, cobalt, or an alloy thereof.

11. The device according to claim 7 wherein said second layer metal is tin or tin alloy including tin/copper, tin/indium, tin/bismuth, tin/silver, and tin/lead.

12. The device according to claim 7 wherein said second layer thickness is between about 3 and 100 nm.

13. The device according to claim 7 wherein said third layer thickness is between about 10 and 500 nm.

14. A semiconductor device, comprising:
a leadframe having a chip mount pad and a plurality of lead segments, each said segment having a first end near said mount pad and a second end remote from said mount pad;
said leadframe comprising a base metal and a first adherent layer of nickel covering said base metal;
said leadframe further comprising an adherent second metal layer of tin, and an adherent third layer of tin selectively covering areas intended for attachment to external parts;
an integrated circuit chip attached to said mount pad;
bonding wires interconnecting said chip and said first segment ends, wherein said interconnection includes bonds through said second layer to said first layer;
encapsulation material covering said chip, bonding wires and said first ends of said lead segments, leaving uncovered leadframe parts intended for attachment to external parts.

15. The device according to claim 14 wherein said base metal is copper, copper alloy, brass, aluminum, iron-nickel alloy, or invar.

16. The device according to claim 14 wherein said second layer thickness is between about 3 and 100 nm.

17. The device according to claim 14 wherein said third layer thickness is between about 10 and 500 nm.
